(19) United States
(12) Patent Application Publication
(10) Pub. No.: US 2026/0086152 A1
(43) Pub. Date: Mar. 26, 2026

(54) METHOD AND APPARATUS FOR MONITORING OVERCURRENT CONDITIONS IN SWITCHES FOR SEMICONDUCTOR DEVICE TESTING

(71) Applicant: Xcerra Corporation, Norwood, MA (US)

(72) Inventor: Stefen Boyd, Beaverton, OR (US)

(21) Appl. No.: 18/898,419

(22) Filed: Sep. 26, 2024

(51) Int. Cl. G01R 31/327; G01R 19/165; G01R 31/26

(52) U.S. Cl. CPC G01R 31/3278; G01R 19/16504; G01R 19/16528; G01R 19/16571; G01R 31/2601

(57) ABSTRACT

An overcurrent monitoring method which can be implemented by computer program instructions executed by one or more hardware processors. In some embodiments, the method can include providing in a semiconductor device tester a device under test, controlling testing signals to the device under test by operation of an electromechanical switch electrically coupled to the device under test, monitoring for an overcurrent condition in the electromechanical switch by directly measuring a testing signal from the electromechanical switch during the operation thereof using a current measurement sensor directly serially connected to the electromechanical switch and determining whether the overcurrent condition has been detected using a detection circuitry electrically coupled to the current measurement sensor. The method can make use of monitoring circuitry to generate excess current signals.

### BACKGROUND

### Field

The disclosed technology generally relates to monitoring current flow through switches, and more particularly to monitoring current flow through electromechanical switches during testing of electronic devices in semiconductor testers.

### Description of the Related Art

A semiconductor device tester is used in the semiconductor industry to test electric devices. The semiconductor device tester conducts testing based on predetermined settings which are dependent upon the characteristics of semiconductor device to be tested. During testing, various testing systems configured to manipulate the input device's operating conditions are applied to the input device and the result is recorded.

The semiconductor device being tested, often referred to as device under test (“DUT”) is subjected to various input signals to obtain output signals, which may be indicative of the functionalities and performance of the DUT. During electrical testing, the electric devices may be first electrically connected to a contactor which includes a set of pins for delivering the input signals to the DUT. These pins come into contact with the input leads of the DUT.

During testing, controlling and monitoring testing signals to the DUT can involve use of various switches to control signals delivered to the DUT. The switches are fundamental components for controlling, among other things, current flow to the DUT by completing or breaking an electrical testing circuit. The switches may be electronic and/or mechanical. Examples of switches include piezo switches, capacitive switches, relays, diodes, transistors and thyristors, to name a few. The performance and reliability of the switches can in turn affect the performance and reliability of the semiconductor device tester.

### SUMMARY

A method of monitoring an electromechanical switch for overcurrent during testing of a device under test (DUT) comprises serially connecting the electromechanical switch to the DUT and controlling testing signals to the DUT by operation of an electromechanical switch electrically coupled to the DUT. The method additionally comprises monitoring for an overcurrent condition in the electromechanical switch by directly measuring a testing signal from the electromechanical switch during the operation thereof using a current measurement sensor directly serially connected to the electromechanical switch. The method additionally comprises generating a comparison signal using a detection circuitry electrically coupled to the current measurement sensor, where the comparison signal is indictive of a comparison between the testing signal and a reference threshold current. The method further comprises determining whether the overcurrent condition has been detected using a monitoring circuitry electrically coupled to the detection circuitry.

An apparatus configured for monitoring an electromechanical switch for overcurrent during testing of a device under test (DUT) comprises an electromechanical switch configured to electrically serially couple to the DUT to control testing signals delivered to the DUT. The apparatus additionally comprises a current measurement sensor directly serially connected to the electromechanical switch and configured for monitoring for an overcurrent condition in the electromechanical switch by directly measuring a testing signal from the electromechanical switch during the operation thereof. The apparatus additionally comprises a detection circuitry electrically coupled to the current measurement sensor and configured to generate a comparison signal, where the comparison signal is indictive of a comparison between the testing signal and a reference threshold current. The apparatus further comprises a monitoring circuitry electrically coupled to the detection circuitry and configured to determine whether the overcurrent condition has been detected.

### BRIEF DESCRIPTION OF THE DRAWINGS

Embodiments of this disclosure will be described, by way of non-limiting example, with reference to the accompanying drawings.

FIG. 1 is a schematic diagram of a semiconductor device tester.

FIG. 2 is a schematic diagram of a semiconductor device tester including a system for monitoring for overcurrent conditions during testing of a device under test, according to embodiments.

FIG. 3 is a flow chart illustrating a method of monitoring an electromechanical switch for overcurrent during switching, according to embodiments.

FIG. 4A is a flow chart illustrating a method of monitoring for overcurrent conditions through an electromechanical switch which is newly closed, according to embodiments.

FIG. 4B is a flow chart illustrating a method of monitoring for overcurrent conditions through an electromechanical switch which is about to open, according to embodiments.

FIG. 5 is a chart depicting an example method of monitoring for overcurrent conditions through an electromechanical switch using a serial peripheral interface, according to embodiments.

FIG. 6 is a schematic diagram depicting a computer system adapted for monitoring overcurrent conditions, according to embodiments.

### DETAILED DESCRIPTION

The following detailed description of certain embodiments presents various descriptions of specific embodiments. However, the innovations described herein can be embodied in a multitude of different ways, for example, as defined and covered by the embodiments. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the illustrated elements. Further, some embodiments can incorporate any suitable combination of features from two or more drawings.

The disclosed embodiments relate to systems and methods for monitoring flow of current through a switch in a semiconductor tester. The switch may be configured to electrically connect to a device under test (DUT) to complete a testing circuit.

Some switches, e.g., electromechanical switches, are not designed to repeatedly handle high levels of current flow during switching. Activating or deactivating switches while flowing current therethrough, sometimes referred to in the industry as “hot switching,” can cause various problems, including malfunctioning and/or premature degradation of the switches. Hot switching can be particularly detrimental when current flows through the electromechanical switches that are undergoing mechanical motion associated with switching. For example, mechanical components undergoing contact switching can experience bounces. When switches undergo such mechanical motions, undesirably high electric field conditions can develop between contacting components, which can in turn lead to uncontrollable events such as arcing, thereby substantially reducing of the lifetime of the switches. Thus, there is a need for accurate monitoring for excessive current flow during activating and deactivating switches in a semiconductor tester. Accordingly, particular embodiments relate to monitoring the switch while being opened or closed and current settling after closing, to detect excessive current flow through the switch. The monitored switch may be an electromechanical switch serially connected to the DUT. Ensuring an electromechanical switch serially connected to a DUT is not flowing excessive current can be important for ensuring both switches and electric devices are not exposed to excessive levels of current (hereafter also referred to as “overcurrent conditions”). Thus, there is a need for tracking instances of excessive current to identify issues which cause overcurrent conditions.

### Overcurrent Monitoring Method

Aspects of this disclosure relate to a method of monitoring a switch, e.g., an electromechanical switch, for overcurrent conditions for improved reliability, efficiency, and/or cost of electrical testing semiconductor devices. The method provides for monitoring and/or controlling testing signals for a device under test (DUT) using the switch, e.g., a serially connected electromechanical switch, within a semiconductor device tester. The method may account for the electromechanical switch being closed or open as well as signals to close and open the electromechanical switch. A DUT can include, but is not limited to, semiconductor device components, including packaged and unpackaged integrated circuit (IC) dies including monolithically integrated IC dies as well as bonded or stacked IC dies that include passive and/or active circuitry. The method may be performed on a singulated IC die or at wafer-level prior to singulation. Such dies can include integrated circuits, such as logic circuitry, volatile and nonvolatile memory circuitry, power delivery circuitry, photonic integrated circuitry, to name a few.

Various electromechanical switches utilize contacts, e.g., metal-to-metal contacts, for activating or deactivating. Activating or deactivating an electromechanical switch while a voltage or current is applied across the contacts can accelerate degradation and failure of the electromechanical switches due to contact erosion. Application of a voltage or current (DC or AC) across the switch contacts during the transition process from open to closed and vice versa. is referred to as “hot switching.” Without being bound to any theory, hot switching is believed to accelerate degradation and failure of electromechanical switches in part due to material transfer, which can in turn be caused by arcing, field emission, field evaporation, Joule heating, and electromigration to name a few. Thus, it is desirable to monitor and limit the exposure of electromechanical switches to hot switching conditions.

Numerous challenges arise in limiting exposure of electromechanical switches to overcurrent conditions (which can increase rates of degradation of electromechanical switches), especially electromechanical switches electrically connected to DUTs with electronic and mechanical components sensitive to excess levels of current. One such challenge is tracking levels of electrical current through electromechanical switches in a resource efficient manner. Some methods serially connect a solid-state device to the electromechanical switch, (e.g., a photo metal-oxide-semiconductor (photoMOS), a device which can operate as an electrical switch), which can open and close a corresponding circuit whenever an electromechanical switch opens or closes to limit instances of excess current, like signal bounce, through the electromechanical switch. However, while such a method can reduce exposure of electromechanical switches to overcurrent conditions, the method also comes with extra cost and consumption of physical space.

To address these and other needs, the disclosed embodiments include providing in a semiconductor device tester a DUT, controlling testing signals to the DUT by operating an electromechanical switch electrically connected to the DUT, monitoring for overcurrent conditions in the electromechanical switch, and determining whether an overcurrent condition has been detected. In some embodiments, a semiconductor device tester can be automatic test equipment, a device including electric and mechanical devices which automatically expose a DUT to one or more tests, either by moving the DUT between testing stations or altering tests applied to the DUT in some other manner.

### Overcurrent Monitoring System

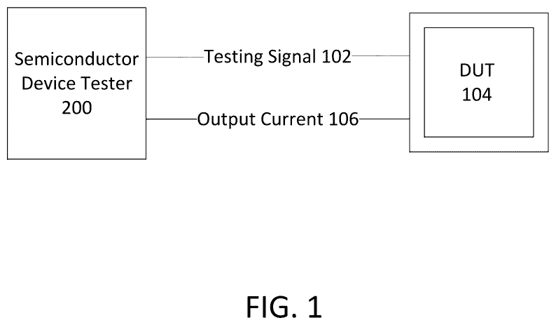

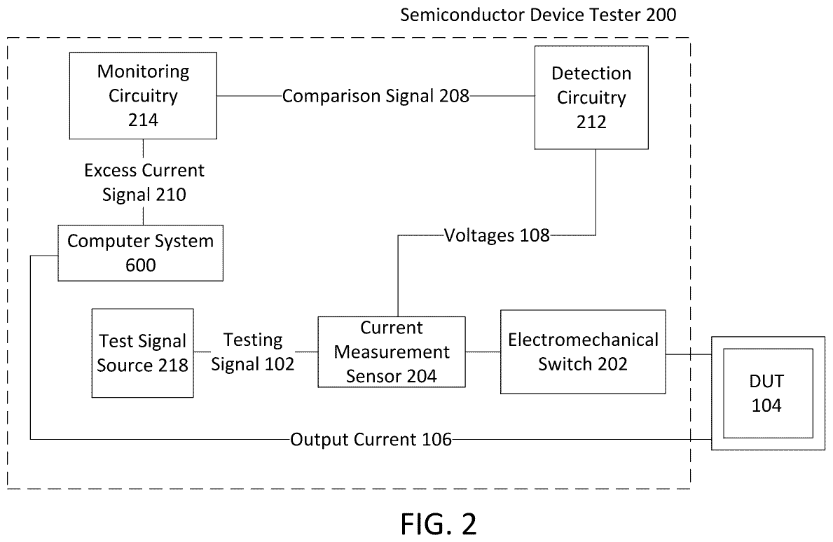

Generally, aspects of the present disclosure relate to systems and methods of monitoring electrical current levels to detect overcurrent conditions across an electromechanical switch (“switch”) electrically coupled with a DUT, while accounting for signals to open and close the electromechanical switch and corresponding electric current settling time. FIG. 1 is an illustrative example of a semiconductor device tester 200 including a device under test (DUT) 104 configured to receive a testing signal 102 and output an output current 106. FIG. 2 is an illustrative embodiment of a semiconductor testing apparatus containing a semiconductor device tester 200 including a device under test (DUT) 104 serially connected to a switch 202. The DUT 104 or the switch 202 is configured to receive a testing signal 102 and output an output current 106. The testing signal 102 can be provided by a test signal source 218. In some embodiments, the output current 106 can be received by the test signal source 218 or a computer system 600. The testing signal characteristics are used to determine whether an overcurrent condition is present in the switch 202 during activation and deactivation thereof using a current measurement sensor 204. It will be appreciated that the relative order of the DUT 104, the electromechanical switch 202 and the current measurement sensor 204 can be interchanged. For example, while in the illustrated arrangement the DUT 104 is illustrated as being downstream of the electromechanical switch 202 and the current measurement sensor 204, in other arrangements the electromechanical switch 202 and the current measurement sensor 204 can be downstream of the DUT 104. In another example, while in the illustrated arrangement the current measurement sensor 204 is upstream of the electromechanical switch 202, in other arrangements the current measurement sensor 204 can be downstream of the electromechanical switch 202.

An electrical signal (“signal”) can be an electrical current and/or voltage capable of being passed through a circuit and/or electrical/electromechanical device. Signals can be steady-state, oscillating, or any combination of waveforms and amplitudes. In some embodiments, without limitation, signals can correspond to levels of current ranging from 1 μA to 100 μA. In some embodiments, without limitation, signals can correspond to levels of voltage ranging from 1 μV to 100 μV.

The DUT 104 can be an integrated circuit or any other electrical device composed of silicon, another semiconductor, or a combination of semiconductors. A DUT can be placed into a semiconductor device tester for various parametric testing for functionality, performance and reliability, including current, voltage, power, or any other metric. Within semiconductor device testers, some tests can include electronically connecting a testing signal to one or more components of a DUT. A testing signal can be electrical current meant to be applied to, and cause a response by, a DUT. A testing signal can be configured to cause a DUT to undergo operations like computational tasks or experience conditions like specified levels of heat produced directly or indirectly by passing the testing signal to and through the DUT. To control flow of current to and through a DUT, an electromechanical switch can be electrically coupled to a testing signal 102 or output current 106 of the DUT. By supplying a signal to an electromechanical switch electrically serially coupled to a DUT, modulating the electromechanical switch (causing the electromechanical switch to be opened or closed) can control testing signals delivered to the DUT.

The switch 202 may be an electromechanical switch, which is an electrical and mechanical device that opens or closes an electrical circuit (“circuit”) to control a transmission of an electrical signal, e.g., a voltage or current signal, through the circuit by modulating an electrical connection between an input terminal, or a portion of the electromechanical switch which receives a signal, and an output terminal, or a portion of the electromechanical switch from which a signal is emitted into the broader circuit. An electrical current supplied to an input terminal of an electromechanical switch can be a testing signal 102 and an electrical current which is supplied by an output terminal of an electromechanical switch can be an output signal 106. An electromechanical switch can receive an electrical modulating signal (“modulating signal”) at a modulating terminal which causes application of mechanical forces to open or close the circuit by causing physical connection or disconnection of electrical contacts internal to the electromechanical switch. For example, the electromechanical switch may employ a piezoelectric to translate the modulating signal to the mechanical forces. An electromechanical switch can be electrically connected into a series circuit (“serially connected”) with a test signal source and a device under test (“DUT”), allowing the electromechanical switch to control testing signals delivered to the DUT. A circuit can be composed of metal or another material with a high electrical conductivity capable of passing an electrical signal through the circuit and to each device electrically coupled with the circuit.

Electromechanical switches have limited life cycles or a maximum number of times each electromechanical switch can cycle between being open and closed before the electromechanical switch is likely to experience damage severe enough to become nonfunctional. An electromechanical switch's life cycle derives from electrical and mechanical components internal to the electromechanical switch experiencing degradation through physical modulation, contact and/or carrying an electrical current - both actions have a tendency to break down or otherwise physically alter components into nonfunctioning, or less functional, states. A life cycle can further be reduced by a corresponding electromechanical switch carrying a quantity of electrical current (amperage, or “amps”) above a certain level, e.g., the level provided by a manufacturer of the electromechanical switch. For example, if an electromechanical switch is rated for 100,000 cycles with a maximum electrical current of 10 microamps, consistently passing an electrical current of 15 microamps through the electromechanical switch can cause the life cycle to reduce to 75,000.

In some embodiments, the electromechanical switch can be a micro-electro-mechanical-system (“MEMS”) switch, which is a miniature device or system which incorporates both electronic and mechanical components to control the flow of an electrical signal. A MEMS switch electrically connected to a circuit can receive a testing signal and a modulating signal to control flow of the testing signal through the circuit. Modulating a testing signal with a MEMS switch can include receiving a modulating signal which causes a mechanical device, e.g., a cantilever, within the MEMS to physically modulate or alter its position to open or close a circuit.

In some embodiments, the electromechanical switch can be an electromechanical relay or micro relay, which is an electromechanical device that operates by using an electromagnet to mechanically open or close electrical contacts. A relay can serve as a remote-controlled switch, allowing a low-power signal to control a higher-power circuit. Relays are widely used in electrical and electronic circuits for various purposes, such as controlling high-voltage circuits with low-voltage signals, providing electrical isolation between different parts of a circuit, and allowing automatic control of electrical devices.

When an electromechanical switch such as a relay is closed, two electrical terminals, one for input and one for output, make electrical contact. When the switch is opened, the two electrical terminals break physical contact.

When a relay (among other electromechanical switches) closes, a phenomenon called signal bounce can occur. Physically, signal bounce refers to when two electrical contacts initially touch after being brought together, wherein physically moving together the electrical contacts can result in a physical bouncing action as the electrical contacts collide, which can cause significant variation in electrical conductivity between the contacts. The significant variation can result in a signal being carried across the contacts to increase and/or decrease in amplitude at a rapid and/or unpredictable manner. When a corresponding level of current is measured during the physical bouncing, the level of current can rapidly increase and/or decrease above and below a desired level. For example, a desired current through a circuit can be 5 microamps. If a relay is closed and signal bounce occurs, a measured amperage through the circuit can oscillate between 3 and 7 microamps for a time until settling at 5 microamps. Apart from excess levels of current leading to an increased rate of degradation in an electromechanical switch, passing a current which exceeds a desired level into a DUT can also cause structural damage to one or more components of the DUT and can result in the DUT being nonfunctional. Thus, tracking instances of excess current through an electromechanical switch can assist efforts to maintain long-term functionality of electromechanical switches and DUTs.

Still referring to FIG. 2, monitoring electrical current through an electromechanical switch can be performed using a current measurement sensor 204, which may be a passive component which receives a directly measured testing signal 102 current or voltage, according to embodiments. In some embodiments, monitoring does not include using an active solid-state device serially connected to the electromechanical switch. In some embodiments, a current measurement sensor 204 can be an ammeter serially connected to a test signal source 218 and an electromechanical switch. In some embodiments, a current measurement sensor 204 can be a resistor serially connected to an electromechanical switch located downstream of the resistor, wherein a testing signal 102 from the resistor can be measured by measuring a voltage across the resistor and applying the voltage to Ohm's Law. Ohm's law can be represented by the equation: I=V/R, wherein I refers to electrical current (in this case, the testing signal through a resistor), V refers to a voltage across a resistor, and R refers to resistance of a resistor. A voltage across a resistor can be a voltage differential between a first voltage measured at an input to the resistor and a second voltage measured at an output of the resistor.

It will be appreciated that FIG. 2 shows a relative order of the DUT 104, the electromechanical switch 202, and the current measurement sensor 204 which can be interchanged. For example, while in the in the illustrated arrangement the DUT 104 is illustrated as being downstream of the electromechanical switch 202 and the current measurement sensor 204, in other arrangements, the electromechanical switch and the current measurement sensor 204 can be downstream of the DUT 104. Similarly, in another example, while in the illustrated arrangement the electromechanical switch 202 is illustrated as being downstream of the current measurement sensor 204, in other arrangements, the current measurement sensor 204 can be downstream of the electromechanical switch 202.

A resistor can be a passive, two-terminal electrical device with a measurable electrical resistivity between the two terminals, which can be an input terminal and an output terminal. Resistors can be made of any suitable material or combination of materials with a measurable resistivity. In some embodiments, the resistor can have a resistance between 0.001 Ohms and 1,000,000 Ohms. In some embodiments, other passive electrical devices can be used instead of, or in conjunction with, a resistor or other passive electrical devices to measure current. Other passive electrical devices include capacitors, inductors, and transformers, among others.

When a resistor is used as a current measurement sensor, measuring voltage at and across the resistor can be done by electrically integrating an input and/or output terminal of the resistor with a detection circuit for further processing. In some embodiments, electrically integrating with an input and/or output terminal or a resistor can be done by establishing an electrical connection between either terminal.

Another method for measuring a testing signal 102 through an electromechanical switch involves placing an active solid-state device serially connected to the electromechanical switch. An active solid-state device can be any electrical device which lacks moving parts and which can electrically modulates the flow of electricity. An active solid-state device can be a diode, transistor, thyristor, or photoMOS device, among others. In some embodiments, monitoring an electromechanical switch for overcurrent can be done without using an active solid-state device serially connected to an electromechanical switch.

Still referring to FIG. 2, to receive measured testing signal 102, the current measurement sensor 204 can be electrically connected to detection circuitry 212. In some embodiments, the detection circuitry 212 can be an electric device, electromechanical device, or a combination of electric and mechanical devices configured to receive measurements from a current measurement sensor 204. In some embodiments, the detection circuitry 212 can be an electrical device or plurality of devices configured to receive a first and second voltages 108 and determine a measured testing signal. The detection circuitry 212 can receive a measured testing signal (wherein the detection circuitry 212 can also determine a measured testing signal from voltage measurements) and a reference threshold current, and generate a comparison signal 208 using the measured testing signal and reference threshold current, wherein the comparison signal 208 includes an electrical signal corresponding to whether a measured testing signal or a reference threshold current has a larger amperage. A reference threshold current can be a quantity of electrical current, or binary signal corresponding to a quantity of electrical current, against which the measured testing signals are compared. For example, a refence threshold current can be 5 microamps and a measured testing signal can be 4 microamps. In this example, because the measured testing signal is less than the reference threshold current, the reference threshold current has not been exceeded and a corresponding comparison signal would correlate to the reference threshold current not being exceeded. In some embodiments, a reference threshold current can be an electrical current with a level of amperage against which another current is measured.

In some embodiments, the detection circuitry 212 electrically connected to an electromechanical switch (either directly or through a current measurement sensor) can monitor open and close states of the electromechanical switch. Such monitoring can assist with proper timing for overcurrent monitoring. In some embodiments, monitoring open and close states of an electromechanical switch can be done by detection circuitry being electrically connected to a modulating signal which controls modulation of the electromechanical switch, wherein detection of the modulating signal can cause a corresponding communication to be passed to monitoring circuitry or a computer system. In some embodiments, monitoring open and close states of an electromechanical switch can be done by continuously monitoring current through the electromechanical switch, recording when current through the electromechanical switch drops to zero and when the current is non-zero, and passing the current level of the electromechanical switch to the monitoring circuitry 214 or the computer system 600 for further processing.

Still referring to FIG. 2, in some embodiments, the detection circuitry 212 can be, or can include, a comparator, which can be one or more electrical devices which compare a first signal and a second signal and generate the comparison signal 208, a binary output signal indicating whether the first or second signal is greater. For example, the comparison signal 208 may be a voltage of 5 microvolts corresponding to a measured testing signal exceeding a reference threshold current. For another example, the comparison signal 208 may be 0 volts if a measured testing signal does not exceed the reference threshold current. In some embodiments, the comparison signal 208 may be a current that is proportional to a measured testing signal which exceeds a corresponding reference threshold current. For example, a measured testing signal can be 5 microamps and a reference threshold current can be 3 microamps. In this example, the corresponding comparison signal 208 can have a quantity of 5 microamps. In some embodiments, the detection circuitry 212 can receive a reference threshold current and two voltage readings from a resistor serially connected to an electromechanical switch; convert the voltage readings into a measured testing signal; compare the measured testing signal with the refence threshold current; and generate a corresponding comparison signal 208.

In some other embodiments, the detection circuitry 212 can be, or can include, an analog-to-digital convertor (ADC), which receives analog electrical signals and generates corresponding digital signals, wherein digital signals are binary signals capable of being received and processed by a computer processor or other integrated logic array. An ADC can be composed of multiple logic gates and integrated circuits. In some embodiments, an ADC can be configured to receive a first voltage and second voltage from a resistor serially connected to electromechanical switch and generate a digital signal corresponding to an amplitude of a measured testing signal 102.

In yet some other embodiments, the detection circuitry 212 can include an ADC electrically connected to a comparator. An ADC can receive voltages 108 from the current measurement sensor 204, e.g., a resistor, serially connected to the electromechanical switch 202 and generate a corresponding digital signal electrically connected to a comparator which is also electrically connected to a reference threshold current. The comparator can generate a comparison signal 208 indicating whether one or the other of the digital signal and reference threshold current is larger. In such an instance, the comparator is configured to receive and process a digital signal corresponding to a measured testing signal and an analog or digital reference threshold current measurement.

In yet some other embodiments, the detection circuitry 212 can be, or can include, a digital-to-analog converter (DAC), which receives digital electrical signals and generates corresponding analog signals. A DAC can include multiple logic gates and integrated circuits.

In yet some other embodiments, the detection circuitry 212 can include a DAC electrically connected to a comparator. A DAC can receive a reference threshold current and generate a corresponding analog signal that is received by a comparator which is also electrically connected to the current measurement sensor 204 so as to receive voltages 108 and facilitate generation of a measured testing signal value. The comparator can generate the measured testing signal corresponding to the voltages 108 and a comparison signal 208 indicating whether the analog signal or the measured testing signal is larger. In some embodiments, the comparator is configured to receive a measured testing signal, e.g., a current measurement sensor 204 composed of an ammeter, and a comparison signal 208 indicating whether the analog signal or the measured testing signal is larger.

Still referring to FIG. 2, the comparison signal 208 from the detection circuitry 212 can be received by the monitoring circuitry 214, which can include one or more devices configured to receive the comparison signal 208 and generate a corresponding excess current signal 210. The comparison signal 208 corresponds to whether a measured testing signal or a reference threshold current is larger, but interpreting the comparison signal 208 can be done by the monitoring circuitry 214. The monitoring circuitry 214, which can include a field a field-programmable gate array (FPGA) and/or application specific integrated circuit (ASIC), can be designed and/or programmed to determine whether the comparison signal 208 corresponds to an overcurrent condition or not. The excess current signal 210 can be an electrical signal corresponding to whether an overcurrent condition has occurred and can contain information concerning a quantity of a current experienced during an overcurrent condition. For example, a reference threshold current can be 3 microamps and a measured testing signal can be 5 microamps or 10 microamps. In this example, a resulting excess current signal 210 can be equal in both instances or can be scaled according to the size of the measured testing signal. In this example, if the excess current signal 210 is constant, both the 5 microamps and 10 microamps measured testing signal will correspond to an excess current signal with an amplitude of 1 microamp. In this example, if the excess current signal scales with measured testing signals, the measured testing signal of 5 microamps can correspond to an excess current signal of 5 microamps and the measured testing signal of 10 microamps can correspond to an excess current signal of 10 microamps.

In some embodiments, the detection circuitry 212 can include an ADC, wherein the ADC generates a digital signal corresponding to a measured testing signal. In such embodiments, the monitoring circuitry 214 can receive a reference threshold current, determine whether the corresponding measured testing signal or reference threshold current is larger, and generate an excess current signal.

In some embodiments, the monitoring circuitry 214 can determine the timing for monitoring for overcurrent conditions. In such embodiments, the detection circuitry 212 can detect open and close states of the electromechanical switch 202 and can pass that information to the monitoring circuitry 214, which, through application of internal logic, can adjust monitoring for overcurrent conditions. Monitoring overcurrent conditions includes not only receiving measurements from the current measurement sensor 204, e.g., a resistor, serially connected to an electromechanical switch (which can be relatively passive), but it can also involve providing power to the detection circuitry 212 and/or generating accompanying excess current signals 210. The detection circuitry 212, which can contain internal logic which requires a power supply, can be configured to receive the power supply from the monitoring circuitry 214. Thus, logic internal to the monitoring circuitry 214 can withhold or provide power, by enabling or disabling monitoring for overcurrent conditions consistent with timing determined by the monitoring circuitry 214. With these embodiments, logic internal to the monitoring circuitry 214 can adjust timing of monitoring overcurrent conditions based on open and close states of the corresponding electromechanical switch 202. Furthermore, in some embodiments, the monitoring circuitry 214 can directly receive modulating signals for opening and closing the electromechanical switch 202, thereby allowing direct monitoring of open and close states by the monitoring circuitry 214.

Still referring to FIG. 2, in some embodiments, the monitoring circuitry 214 can generate the excess current signal both if a measured testing signal 102 exceeds a reference threshold current and if the measured testing signal 102 does not exceed the reference threshold current. For example, if a measured testing signal exceeds a reference threshold current, an excess current signal with an amplitude of 5 microamps can be generated, while if the measured testing signal 102 does not exceed the reference threshold current, an excess current signal of 1 amp can be generated. In these embodiments, an excess current signal is generated for each voltage reading received.

In some embodiments, the monitoring circuitry 214 is, or includes, a field programmable gate array (FPGA), which refers to a configurable integrated circuit which can be programmed for a plurality of uses. An FPGA includes one or more logic gates configured to interact with electrically connected signals to perform one or more computations and/or generate one or more corresponding output signals.

In some embodiments, the monitoring circuitry 214 is, or includes, application specific integrated circuits (ASIC), an integrated circuit physically designed and produced to perform a desired functionality. ASICs can serve similar end functions, as FPGAs but are different in that FPGAs are general-user devices which can be updated by the user with software to perform specific tasks, whereas ASICs are manufactured to perform specific tasks.

In some embodiments, the electromechanical switch 202 can be controlled with a serial peripheral interface (SPI).

Still referring to FIG. 2, the excess current signal 210 can be received by a computer system 600 including one or more computer processors and computer-readable medium such as a memory and storage. The computer system 600 can receive the excess current signal 210 and record an instance of an overcurrent condition into the computer-readable memory. In instances in which an excess current signal amplitude corresponds to a measured testing signal amplitude, the excess current signal amplitude can also be recorded onto the computer-readable memory. Contents of the computer-readable memory may be reviewed and used for a plurality of purposes, including aiding in troubleshooting to determine a cause of overcurrent and assisting predictions of remaining lifecycles for corresponding electromechanical switches.

### Testing Rate

Monitoring overcurrent conditions can be continuous, receiving measurements for as long as an electromechanical switch is being utilized, including when the electromechanical switch is closed and open. However, continuous monitoring is computationally expensive and, in certain instances, unnecessary. For example, when an electromechanical switch is open, no current can flow and thus, any monitoring of testing signal levels would be redundant. Instead, a tailored approach can be applied to measure a testing signal when overcurrent conditions are most likely to be detected and when confirming testing signal levels is most relevant.

In some embodiments, when a modulating signal is detected to open or close an electromechanical switch, or when a switch state is changing, monitoring for overcurrent conditions can be continuous until the switch has mechanically settled. As described herein, mechanical settling refers to settling of transient mechanical motions associated with switching movements in electromechanical switches, such as bouncing that may result in repeated and erratic contacts between switching components.

In some embodiments, monitoring overcurrent conditions can be continuous after an electromechanical switch closes and can take place once when a modulating signal to open an electromechanical switch is detected, wherein further monitoring can be ceased until the electromechanical switch is closed. When electromechanical switches close, as previously mentioned, physical bouncing of the electromechanical switches can occur and manifest as overcurrent conditions. To accommodate the physical bouncing, current verification can begin as soon as an electromechanical switch closes. Furthermore, current verification can be continuous until the electromechanical switches have physically settled. When an electromechanical switch receives a modulating signal to open, there can be a delay during which the modulating signal to open has been received but the electromechanical switch has not physically opened its circuit. During this time, the system can perform one instance of overcurrent monitoring, because after that moment, measured testing signal readings will be essentially zero since the circuit is open. Performing the aforementioned overcurrent monitoring prior to the electromechanical switch opening can ensure, prior to pausing further monitoring, that the electromechanical switch is not experiencing an overcurrent condition.

As discussed above, during mechanical settling, an electromechanical switch can experience undesirable mechanical motions such as bouncing. Allowing the electromechanical switch sufficient time to mechanically fully settle before carrying a substantial amount of current can be important for improved reliability and lifetime of the switch. Thus, a settle time—an amount of time during which an electromechanical switch physically settles—can be applied to allow electromechanical switches sufficient time to settle. The settle time for each electromechanical switch can be dependent upon manufacturing specifications provided by the electromechanical switch's manufacturer. In some embodiments, the settle time can be between 0.001 seconds to 5 seconds. During mechanical settling, amplitude of a current being carried through the electromechanical switch can vary relatively widely, exceeding a desired current level, falling below the desired current level, or cycling above and below the desired current level before stability is reached. While an electromechanical switch is mechanically settling, monitoring for overcurrent conditions can take place continuously, so as to ensure detection of overcurrent while a likelihood of overcurrent is high.

In some embodiments, settle times can be determined by a manufacturer of an electromechanical switch. Thus, in some embodiments, monitoring overcurrent conditions continuously after an electromechanical switch is closed can cease being continuous after the settle time reported by the manufacturer has passed.

Recorded overcurrent conditions can be recorded on computer readable memory and can be applied for any number of purposes.

### Overcurrent Monitoring and Detection System

FIG. 1 is an illustrative embodiment of a semiconductor device tester 200 having received therein a device under test (DUT) 104, which in turn is being electrically coupled to a testing signal 102 signal and an output current 106.

The semiconductor device tester 200 can be any mechanical and/or electrical system for testing one or more aspects of a DUT 104. For example, an aspect of a DUT being tested by a semiconductor device tester 200 can be maximum clock speed, maximum clock speed while exposed to high or low temperatures, or any other test. In some embodiments, a semiconductor device tester 200 can be automatic test equipment.

The DUT 104 can be any integrated circuit device or any other electronic device capable of being tested by a semiconductor device tester 200. A DUT can commonly be an integrated circuit, a device manufactured of one or more semiconductors and designed to receive one or more testing signals 102 and perform a task, whether processing, computation, or some other operation.

Within the semiconductor device tester 200, the DUT 104 can be electrically coupled to a testing signal 102, an electrical signal corresponding to a quantity of voltage and current which can expose the DUT 104 to a test and/or cause the DUT 104 to perform a function. A testing signal 102 can be steady-state or variable (for example, a wave function). For example, a testing signal 102 can be an electric current wave function which, when received by a DUT 104, causes the DUT 104 to perform computations. The DUT 104 can also have an electrically coupled output current 106, an electrical signal corresponding to a testing signal 102 having passed through the DUT. An output current 106 can be of a similar character as a corresponding testing signal 102, in terms of amplitude and signal shape, although the output current 106 will tend to be lower in amplitude than a corresponding testing signal 102, but this is not always the case.

Turning to FIG. 2, an example embodiment of a semiconductor device tester 200 having received therein a DUT 104, a current measurement sensor 204, and an electromechanical switch 202 serially connected to the DUT 104. The current measurement sensor 204 can include, e.g., a resistor serially connected to a test signal source 218 and the electromechanical switch 202, whereby an input terminal and/or output terminal of the resistor are electrically connected to a detection circuitry 212, which is electrically connected to monitoring circuitry 214, and which is electrically connected to a computer system 600. As a whole, the tester 200 illustrated in FIG. 2 can be used to perform a method of monitoring a testing signal 102 through the current measurement sensor 204 to check for overcurrent conditions and, if an overcurrent condition is detected, recording the overcurrent condition in computer-readable memory contained within the computer system 600.

The DUT 104, as further described elsewhere in the application, can be an electric device which undergoes one or more tests within a semiconductor device tester 200. The DUT 104 can be a semiconductor device, an electric device composed of one or more semiconductors, and which can be used to perform or assist computational processes.

The electromechanical switch 202 can be a device serially connected to the DUT 104 and which can control a corresponding testing signal 102. The electromechanical switch 202 can receive a modulating signal to open and close, causing a circuit to which the electromechanical switch 202 is serially connected to open and close. In some embodiments, an electromechanical switch 202 can receive a modulating signal (to open or close) from monitoring circuitry 214. Upon activation and deactivation, the electromechanical switch 202 electromechanically forms short and open circuits by moving electrically contacting terminals. In some embodiments, the electromechanical switch 202 can be an electromechanical relay. In some embodiments, the electromechanical switch 202 can be a micro-electro-mechanical-systems (MEMS) switch.

The electromechanical switch 202 can be electrically connected (in some embodiments, via an electrical connection to the current measurement sensor 204) to a test signal source 218 which provides the testing signal 102. A test signal source 218 can be any source of electrical power, including but not limited to: one or more batteries, a generator, a circuit electrically connected to an electrical power grid, or any other source. In some embodiments, the output current 106 can be received by a computer system 600, whereby the output current 106 can be interpreted and processed directly by the computer system 600.

The current measurement sensor 204 can be electrically connected to the test signal source 218 and serially connected to the electromechanical switch 202. The current measurement sensor 204 can be a suitable device for measuring current, e.g., a resistor with a measurable resistivity that can carry electrical current. The current measurement sensor 204 can have an input terminal, corresponding to where an electric signal is fed into the current measurement sensor 204, and an output terminal, corresponding to where an electric signal leaves the current measurement sensor 204. In some embodiments, the current measurement sensor 204 can be serially connected to an electromechanical switch 202 input terminal. In some embodiments, the current measurement sensor 204 can be serially connected to an electromechanical switch 202 output terminal. An electric current flowing through the current measurement sensor 204 serially connected with an electromechanical switch 202 will be the same electric current flowing the electromechanical switch 202. Therefore, if a current through the current measurement sensor 204 is measured, a measured amperage will be equal to what is being passed through the electromechanical switch 202. Current through the current measurement sensor 204 will also be equal to the testing signal 102 from the semiconductor device tester 200.

The detection circuitry 212 can be electrically connected to a first and/or second voltage 108 carried from an input and/or output terminal of a resistor. The detection circuitry 212 can be one or more electrical devices which can receive one or more voltages 108 and generate a comparison signal 208 or a digital signal. In some embodiments, detection circuitry 212 can be, or include, a comparator. In some embodiments, detection circuitry 212 can be, or include, an analog-to-digital-convertor (ADC). In some other embodiments, detection circuitry 212 can be, or include, a digital-to-analog-convertor (DAC). When the detection circuitry 212 includes an ADC and a comparator, voltages 108 can be received by the ADC, a corresponding digital signal can be generated, and the digital signal and a reference threshold current can be received by the comparator, which can generate a comparison signal 208. When detection circuitry 212 includes a DAC and a comparator, a reference threshold current can be received by the DAC, a corresponding analog signal can be generated, and the analog signal and voltages 108 can be received by the comparator, which can generate a comparison signal 208.

A comparison signal 208 can be an electrical signal which corresponds to which of two or more compared signals are larger in quantity (whether in relation to voltage or amperage). The comparison signals 208 can be steady-state or wavefunction. A digital signal 216 can be a binary electrical signal which corresponds to an analog voltage 108. The digital signal 216 can be steady-state or have a waveform function.

The comparison signals 208 can be received by the monitoring circuitry 214, which can include one or more electric devices composed of one or more logic gates which perform a desired functionality and, in some embodiments, can be programmed. In some embodiments, the monitoring circuitry 214 can receive the comparison signal 208 and can determine if the comparison signal 208 corresponds to a measured testing signal 102 being greater or less than a reference threshold current.

In some embodiments, monitoring circuitry 214 is a field-programmable gate array.

In some embodiments, monitoring circuitry 214 is an application specific integrated circuit.

In some embodiments, monitoring circuitry 214 contains an FPGA and an ASIC.

If a measured testing signal 102 is measured to be larger than a reference threshold current, an excess current signal 210 can be generated by monitoring circuitry 214. In some embodiments, the excess current signal 210 can be a constant binary value, meaning the excess current signal 210 serves purely as a notification that an overcurrent condition has occurred. For example, two measured testing signals 102 can be 10 μA and 20 μA and a corresponding reference threshold current for both measured testing signals 102 can be 5 μA. In this example, two excess current signals 210 can be generated, both with amplitudes of 1 μA. In some embodiments, the excess current signal 210 can scale in amplitude according to an amplitude of a corresponding measured testing signal 102 whose amplitude exceeds a reference threshold current. For example, two measured testing signals 102 can be 10 μA and 20 μA and a corresponding reference threshold current for both measured testing signals 102 can be 5 μA. In this example, one excess current signal 210 can have an amplitude of 10 μAmps and another excess current signal can have an amplitude of 20 μA (corresponding to the 10 μA and 20 μA measured testing signals 102 respectively. Excess current signals 210 can be processed and recorded by a computer system 600.

### Method of Monitoring an Electromechanical Switch for Overcurrent

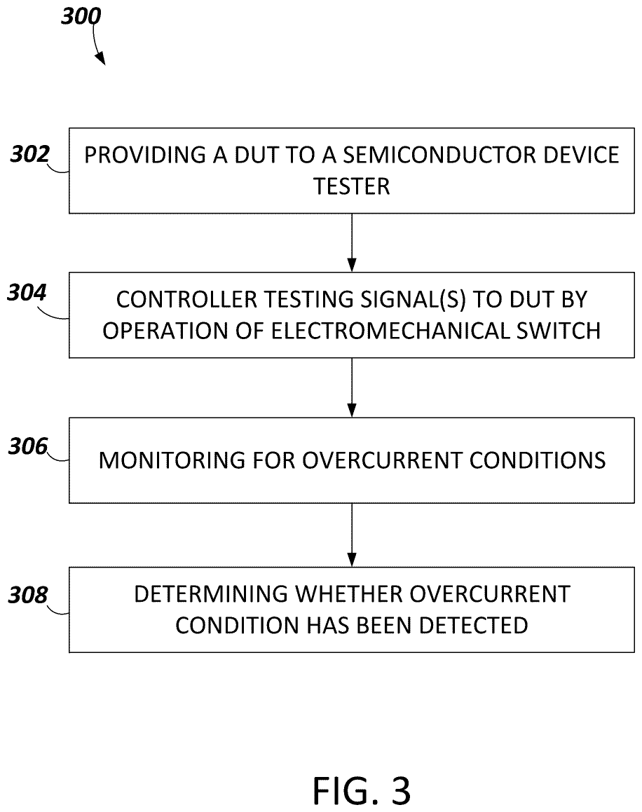

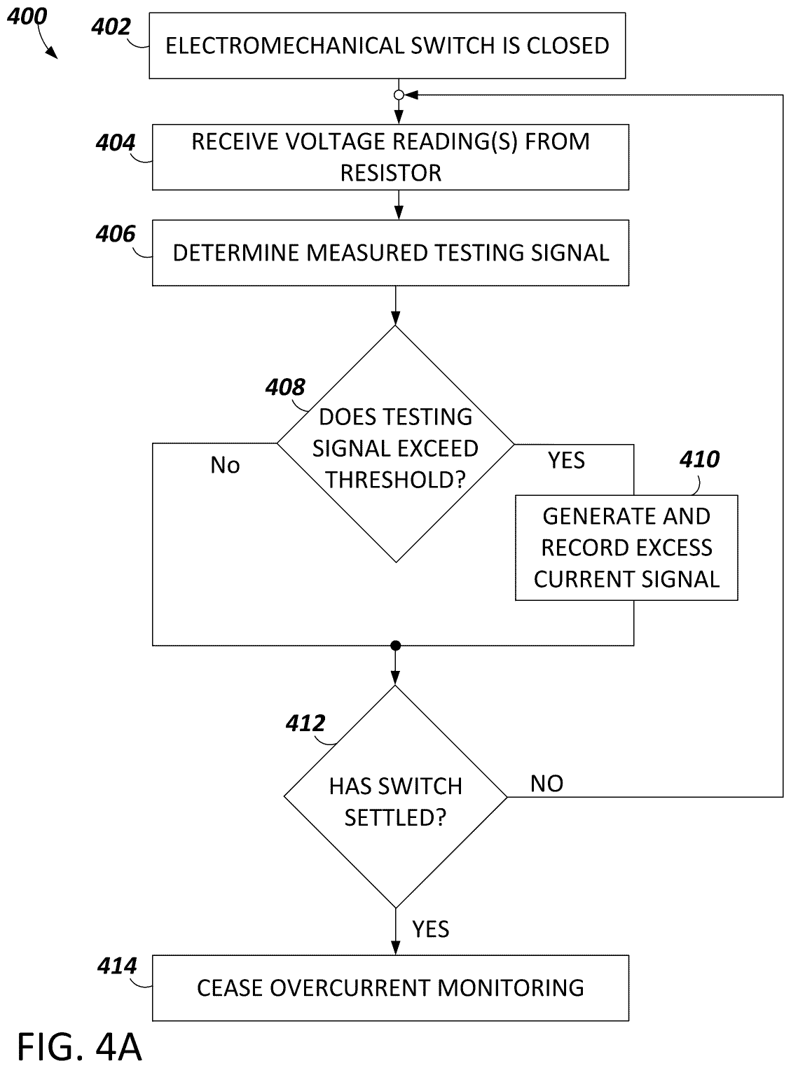

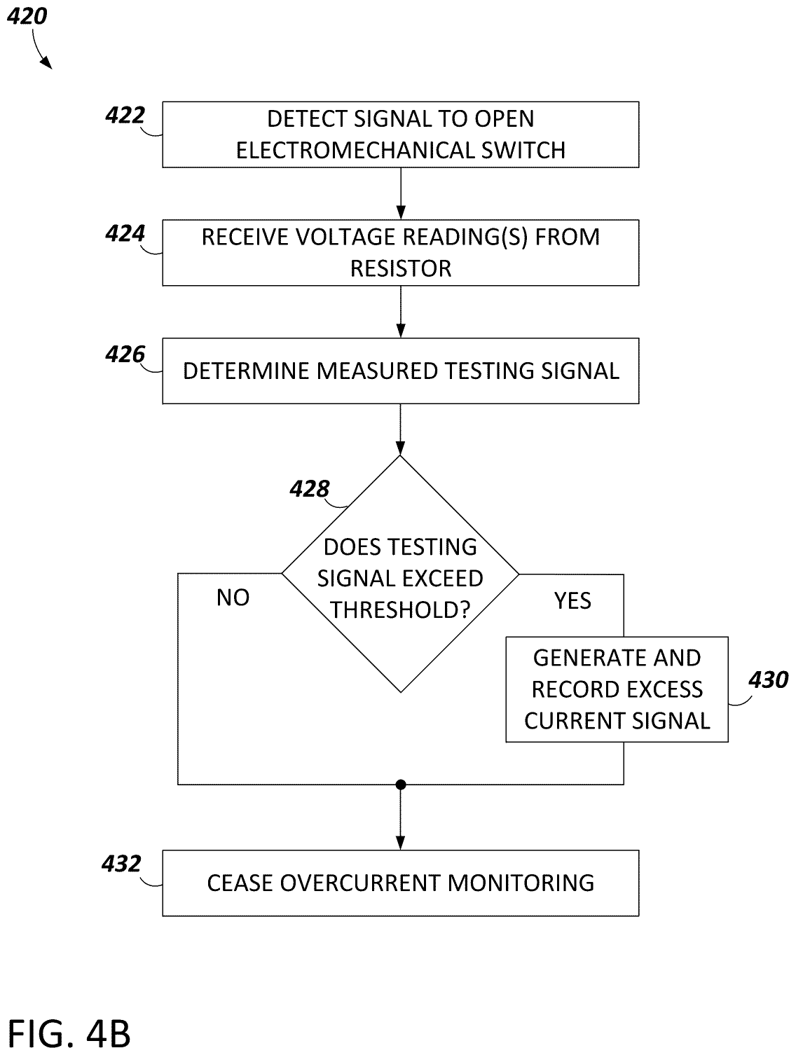

FIG. 3 is a flow chart illustrating a method of monitoring an electromechanical switch for overcurrent during switching, according to embodiments. The method 300 includes providing 302 in a semiconductor device tester a DUT, controlling 304 testing signals to the DUT by operating an electromechanical switch electrically connected to the DUT, monitoring 306 for overcurrent conditions in the electromechanical switch, and determining 308 whether an overcurrent condition has been detected. FIG. 4A illustrates a method 400 including monitoring 306 when the electromechanical switch has just closed, according to embodiments, and FIG. 4B illustrates a method 420 including monitoring 306 when the electromechanical switch is about to be open, according to embodiments. In the following, FIGS. 4A and 4B are described in continued reference to features described above with respect to FIG. 2.

FIG. 4A illustrates a flow chart depicting a method 400 for monitoring overcurrent conditions through an electromechanical switch 202 after, e.g., immediately after, the electromechanical switch has closed. At step 402, a computer system 600 detects that an electromechanical switch 202 has just closed. At step 404, the system begins to receive voltages 108 from the current measurement sensor 204 serially connected with the electromechanical switch 202. At step 406, the system uses the received voltages 108 readings to determine a measured testing signal 102. At step 408, the system can determine if the measured testing signal 102 value exceeds a reference threshold current.

If the measured testing signal 102 value exceeds a reference threshold current, the method 400 proceeds to step 410 to generate an excess current signal 210 and record the excess current signal 210 to a computer memory, wherein the record can include an indicator identifying that an overcurrent condition was measured and/or an amplitude of measured testing signal 102. After recording an overcurrent condition onto memory, the method 400 proceeds to step 412, wherein the electromechanical switch is determined to be settled or not settled. If, at step 408, the measured testing signal 102 does not exceed the reference threshold current, the method moves to step 412, to determine if the current has settled.

Determining if the electromechanical switch has settled can be done by one of numerous methods, including determining if the settle time has passed since the electromechanical switch has closed. If the electromechanical switch has not settled, the method moves to step 404 to receive further voltages 108.

If, at step 408, a measured testing signal 102 is deemed to not exceed a reference threshold current, the method moves to step 412 to determine if the electromechanical switch has settled.

If the electromechanical switch has settled at step 412, the method proceeds to step 414, wherein overcurrent monitoring can cease.

FIG. 4B is a flow chart depicting a method 420 for determining current through an electromechanical switch 202 prior to, e.g., immediately prior to, the electromechanical switch 202 being opened. At step 422, a modulating signal to open an electromechanical switch electrically connected to a DUT is detected, whether by monitoring circuitry, a computer system, or detection circuitry. Prior to the electromechanical switch opening, at step 424, the method 420 can receive a voltages 108 from the current measurement sensor 204 serially connected to the electromechanical switch 202. At step 426, the voltages 108 can be used to determine a measured testing signal 102 through the current measurement sensor 204 and electromechanical switch 202. At step 428, the method determines if the measured testing signal 102 exceeds a reference threshold current. If yes, the method moves to step 430 to generate and record an excess current signal 210 onto compute memory, wherein the record can include an indicator identifying that an overcurrent condition was measured and/or a measured testing signal 102. After recording the measured testing signal 102, the method moves to step 432, where monitoring for overcurrent conditions will cease. Also, if the measured testing signal 102 does not exceed the refence threshold current at step 428, the method similarly moves to step 432.

### Overcurrent Monitoring with SPI

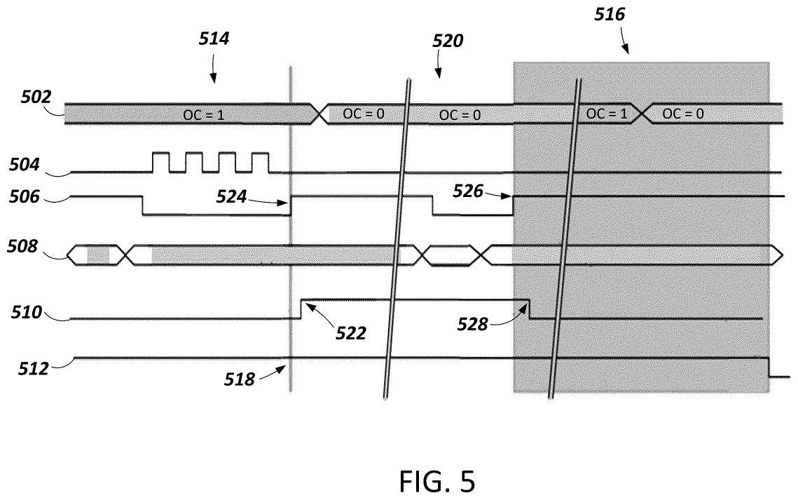

FIG. 5 is a chart 500 depicting an example method of monitoring overcurrent conditions through an electromechanical switch with a serial peripheral interface, according to embodiments. Within the chart 500 is shown a graphical representation of: a signal 502 corresponding to an excess current signal, wherein when an overcurrent (“OC”) value is equal to 1, a measured testing signal exceeds a reference threshold current; a signal 506 corresponding to an electromechanical switch modulating signal; a signal 510 corresponding to a measured open or close state of the electromechanical switch; and several other signals 504, 508, and 512, which are utilized by hardware applying the SPI. As is shown at 514, measurement of a testing signal caused generation of an excess current signal corresponding to an overcurrent position, hence why the OC value is equal to 1. At 524, a signal to open an electromechanical switch is received. As the signal to open is received, a single overcurrent check is performed at 518, prior to the electromechanical switch opening at 522. The signal 502 indicates that an overcurrent condition is detected when the modulating signal 506 indicates the electromechanical switch should be open at time 518. After 522, within the region 520, no overcurrent condition is detected because the electromechanical switch is opened and thus no monitoring is performed. At point 526, a signal to close the electromechanical switch is received and continuous overcurrent monitoring begins, shown by the region 516. Thus, when the electromechanical switch does close, at point 528, overcurrent monitoring has already begun so as to detect all potential instances of overcurrent. As is shown in the region 516, one or more measurements of an overcurrent signal 502 occur, indicating overcurrent while closing the electromechanical switch.

### Computer System

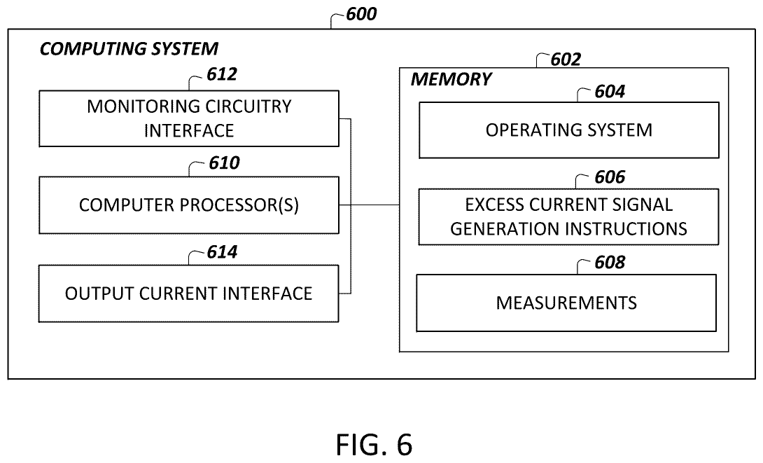

FIG. 6 illustrates an example computer system 600 that may be used in some embodiments to execute the processes and implement the features described above. In some embodiments, the computer system 600 may include: one or more computer processors 610, such as physical central processing units (“CPUs”) or graphics processing units (“GPUs”); computer-readable memory 602, such as high density disks (“HDDs”), solid state drives (“SDDs”), flash drives, and/or other persistent non-transitory computer-readable media; a monitoring circuitry interface 612, such as an IO interface in communication between monitoring circuitry and the computer system 600; and an output current interface 614, such as an IO interface in communication between an output current 106 and the computer system 600, whereby the output current 106 can be received and analyzed by the computer system 600.

The computer-readable memory 602 may include computer program instructions that the computer processor(s) 610 execute(s) in order to implement one or more embodiments. The computer-readable memory 602 can store an operating system 604 that provides computer program instructions for use by the computer processor(s) 610 in the general administration and operation of the computer system 600. The computer-readable memory 602 can also include excess current signal generation instructions 606 for programming a field-programmable gate array to generate an excess current signal from a comparison signal or a digital signal and a reference threshold current, and further for receiving and processing excess current signals. The excess current signal generation instructions 606 can also include instructions for controlling operation of the monitoring circuitry 214. As operation of the monitoring circuitry 214 can direct operation of the detection circuitry 212, controlling the monitoring circuitry 214 can enable an indirect control of the detection circuitry 212. The computer-readable memory 602 can also include measurements 608 of observed overcurrent conditions.

### Terminology

Depending on the embodiment, certain acts, events, or functions of any of the processes or algorithms described herein can be performed in a different sequence, can be added, merged, or left out altogether (e.g., not all described operations, sequencing, or events are necessary for the practice of the algorithm). Moreover, in certain embodiments, operations or events can be performed concurrently, e.g., through multi-threaded processing, interrupt processing, or multiple processors or processor cores or on other parallel architectures, rather than sequentially.

The various illustrative logical blocks, modules, routines, and algorithm steps described in connection with the embodiments disclosed herein can be implemented as electronic hardware, or combinations of electronic hardware and computer software. To clearly illustrate this interchangeability, various illustrative components, blocks, modules, and steps have been described above generally in terms of their functionality. Whether such functionality is implemented as hardware, or as software that runs on hardware, depends upon the particular application and design constraints imposed on the overall system. The described functionality can be implemented in varying ways for each particular application, but such implementation decisions should not be interpreted as causing a departure from the scope of the disclosure.

Moreover, the various illustrative logical blocks and modules described in connection with the embodiments disclosed herein can be implemented or performed by a machine, such as a computer processor device, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A computer processor device can be a microprocessor, but in the alternative, the processor device can be a controller, microcontroller, or state machine, combinations of the same, or the like. A processor device can include electrical circuitry configured to process computer-executable instructions. In another embodiment, a processor device includes an FPGA or other programmable device that performs logic operations without processing computer-executable instructions. A processor device can also be implemented as a combination of computer devices, e.g., a combination of a DSP and a microprocessor, a plurality of microprocessors, one or more microprocessors in conjunction with a DSP core, or any other such configuration. Although described herein primarily with respect to digital technology, a processor device may also include primarily analog components. For example, some or all of the algorithms described herein may be implemented in analog circuitry or mixed analog and digital circuitry. A computer environment can include any type of computer system, including, but not limited to, a computer system based on a microprocessor, a mainframe computer, a digital signal processor, a portable computer device, a device controller, or a computational engine within an appliance, to name a few.

The elements of a method, process, routine, or algorithm described in connection with the embodiments disclosed herein can be embodied directly in hardware, in a software module executed by a processor device, or in a combination of the two. A software module can reside in RAM memory, flash memory, ROM memory, EPROM memory, EEPROM memory, registers, hard disk, a removable disk, a CD-ROM, or any other form of a non-transitory computer-readable storage medium. An exemplary storage medium can be coupled to the processor device such that the processor device can read information from, and write information to, the storage medium. In the alternative, the storage medium can be integral to the processor device. The processor device and the storage medium can reside in an ASIC. The ASIC can reside in a user terminal. In the alternative, the processor device and the storage medium can reside as discrete components in a user terminal.

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without other input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Disjunctive language such as the phrase “at least one of X, Y, Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B and C” can include a first processor configured to carry out recitation A working in conjunction with a second processor configured to carry out recitations B and C.

While the above detailed description has shown, described, and pointed out novel features as applied to various embodiments, it can be understood that various omissions, substitutions, and changes in the form and details of the devices or algorithms illustrated can be made without departing from the spirit of the disclosure. As can be recognized, certain embodiments described herein can be embodied within a form that does not provide all of the features and benefits set forth herein, as some features can be used or practiced separately from others. The scope of certain embodiments disclosed herein is indicated by the appended claims rather than by the foregoing description. All changes which come within the meaning and range of equivalency of the claims are to be embraced within their scope.

What is claimed is:

1. A method of monitoring an electromechanical switch for overcurrent during testing of a device under test (DUT), the method comprising:
serially connecting the electromechanical switch to the DUT;
controlling testing signals to the DUT by operation of an electromechanical switch electrically coupled to the DUT;
monitoring for an overcurrent condition in the electromechanical switch by directly measuring a testing signal from the electromechanical switch during the operation thereof using a current measurement sensor directly serially connected to the electromechanical switch;
generating a comparison signal using a detection circuitry electrically coupled to the current measurement sensor, the comparison signal indictive of a comparison between the testing signal and a reference threshold current; and
determining whether the overcurrent condition has been detected using a monitoring circuitry electrically coupled to the detection circuitry.

2. The method of claim 1, wherein the electromechanical switch is provided in a semiconductor device tester.

3. The method of claim 1, wherein the electromechanical switch comprises an electromechanical relay or a micro-electro-mechanical-system (MEMS) switch.

4. The method of claim 1, wherein directly measuring the testing signal does not include using an active solid state device serially connected to the electromechanical switch.

5. The method of claim 1, wherein the current measurement sensor comprises a resistor serially connected to the electromechanical switch, and wherein measuring the testing signal comprises measuring a voltage across the resistor.

6. The method of claim 5, wherein the resistor has a resistance between 0.001 Ohms and 1,000,000 Ohms.

7. The method of claim 5, wherein generating the comparison signal using the detection circuitry comprises:
using an analog-to-digital converter (ADC), to receive the voltage and generate a digital signal,
receiving, by a comparator, the digital signal and the reference threshold current, and
generating, with the comparator, the comparison signal comparing the digital signal to the reference threshold current.

8. The method of claim 5, wherein generating the comparison signal using the detection circuitry comprises:
using a digital-to-analog converter (DAC) to receive the reference threshold current and generate an analog signal,
receiving, by a comparator, the analog signal and the voltage, and
generating, with the comparator, the comparison signal comparing the analog signal to voltage.

9. The method of claim 5, wherein using a monitoring circuitry comprises receiving, by an application specific integrated circuit or a field-programmable gate array, the comparison signal.

10. The method of claim 9, wherein determining whether the overcurrent condition has been detected further comprises generating, by the monitoring circuitry, an excess current signal, and wherein the method further comprises storing the excess current signal in a memory.

11. The method of claim 10, wherein the memory is computer memory in a computer system electronically coupled to the monitoring circuitry.

12. The method of claim 1, wherein monitoring for the overcurrent condition and determining whether the overcurrent condition has been detected are performed once when the electromechanical switch receives a signal to open.

13. The method of claim 1, wherein monitoring for the overcurrent condition and determining whether the overcurrent condition has been detected are performed continuously from when the electromechanical switch is closed until a settle time has passed.

14. An apparatus configured for monitoring an electromechanical switch for overcurrent during testing of a device under test (DUT), the apparatus comprising:
an electromechanical switch configured to electrically serially couple to the DUT to control testing signals delivered to the DUT;
a current measurement sensor directly serially connected to the electromechanical switch and configured for monitoring for an overcurrent condition in the electromechanical switch by directly measuring a testing signal from the electromechanical switch during the operation thereof;
a detection circuitry electrically coupled to the current measurement sensor and configured to generate a comparison signal, the comparison signal indictive of a comparison between the testing signal and a reference threshold current; and
a monitoring circuitry electrically coupled to the detection circuitry and configured to determine whether the overcurrent condition has been detected.

15. The apparatus of claim 14, wherein the apparatus is a semiconductor device tester.

16. The apparatus of claim 14, wherein the electromechanical switch comprises an electromechanical relay or a micro-electro-mechanical-system (MEMS) switch.

17. The apparatus of claim 14, wherein an active solid state device is not serially connected to the electromechanical switch.

18. The apparatus of claim 14, wherein the current measurement sensor comprises a resistor serially connected to the electromechanical switch, and wherein measuring the testing signal comprises measuring a voltage across the resistor.

19. The apparatus of claim 18, wherein the resistor has a resistance between 0.001 Ohms and 1,000,000 Ohms.

20. The apparatus of claim 18 wherein the detection circuitry comprises:
an analog-to-digital converter (ADC) configured to receive the voltage and generate a digital signal, and
a comparator configured to receive the digital signal and a reference threshold current and to generate a comparison signal comparing the digital signal to the reference threshold current.

21. The apparatus of claim 18, wherein the detection circuitry comprises:
a digital-to-analog converter (DAC) configured to receive a reference threshold current and generate an analog signal, and
a comparator configured to receive the analog signal and the voltage and to generate a comparison signal comparing the analog signal to voltage.

22. The apparatus of claim 18, wherein the monitoring circuitry comprises an application specific integrated circuit or a field-programmable gate array configured to generate an excess current signal.
